(19) United States
(12) Patent Application Publication
(10) Pub. No.: US 2026/0190752 A1
(43) Pub. Date: Jul. 2, 2026

(54) Display Device

(71) Applicant: LG Display Co., Ltd., Seoul (KR)

(72) Inventors: GyuHo Lee, Seoul (KR); Sinchul Kang, Gimpo-si (KR); Sungjin Park, Seoul (KR)

(21) Appl. No.: 19/400,728

(22) Filed: Nov. 25, 2025

(30) Foreign Application Priority Data
Dec. 30, 2024 (KR) 10-2024-0201364

(51) Int. Cl. H10K 59/80; H10K 102/00

(52) U.S. Cl. CPC H10K 59/80; H10K 2102/311

(57) ABSTRACT

A display device presented herein comprises a display panel including a folding area and non-folding areas located on both sides of the folding area and including a base substrate and a display part disposed on the base substrate, a first support substrate configured to support the display panel from a lower portion of the display panel and including a plurality of opening patterns corresponding to the folding area, a second support substrate disposed between the display panel and the first support substrate and including an opening corresponding to the folding area, and a support member disposed below the base substrate and disposed to correspond to the opening.

### CROSS-REFERENCE TO RELATED APPLICATIONS

The present application claims the priority to Republic of Korea Patent Application No. 10-2024-0201364 filed on Dec. 30, 2024, which is incorporated herein by reference in its entirety.

### BACKGROUND

### Field

The present disclosure relates to a display device, and more particularly, to a display device including a support pattern in a folding area.

### Discussion of Related Art

Recently, as it enters the information age, the field of displays that visually express electrical information signals has been rapidly developed, and in response to this, various display devices with excellent performances such as thin-thickness, light weight, and low power consumption have been developed. Specific examples of such a display device include a liquid crystal display (LCD), a plasma display panel device (PDP), a field emission display device (FED), and an organic light emitting display device (OLED).

Recently, flexible display devices manufactured to display images even when bent or folded like paper are attracting attention as next-generation display devices. The flexible display device may be classified into an unbreakable display device having high durability, a bendable display device which may be bent without breaking, a rollable display device which may be rolled, and a foldable display device which may be folded. Such a flexible display device has advantages in space utilization, interior, and design, and may have various application fields.

### SUMMARY

An object to be achieved by the present disclosure is to provide a display device capable of minimizing or at least reducing a folding stress in a folding area.

Another object to be achieved by the present disclosure is to provide a display device capable of suppressing the occurrence of wrinkles in a folding area.

Still another object to be achieved by the present disclosure is to provide a display device capable of maintaining excellent appearance quality and durability.

Objects of the present disclosure are not limited to the above-mentioned objects, and other objects, which are not mentioned above, can be clearly understood by those skilled in the art from the following descriptions.

According to one or more embodiments of the present disclosure, a display device includes a display panel including a folding area and non-folding areas positioned at both sides of the folding area and including a base substrate and a display part disposed on the base substrate, a first support substrate configured to support the display panel from a lower portion of the display panel and including a plurality of opening patterns corresponding to the folding area, a second support substrate disposed between the display panel and the first support substrate and including an opening corresponding to the folding area, and a support member disposed under the base substrate and disposed to correspond to the opening.

A display device according to one or more other embodiments of the present disclosure comprises a display panel including a folding area and non-folding areas positioned at both sides of the folding area and including a base substrate and a display part disposed on the base substrate, a support member disposed below the display panel and disposed to correspond to the folding area, a first adhesive layer disposed below the display panel and disposed to surround the support member, a first support substrate disposed below the first adhesive layer and including a first opening corresponding to the support member, a second adhesive layer disposed below the first support substrate and including a second opening corresponding to the support member, and a plurality of opening patterns disposed below the second adhesive layer and corresponding to the folding area.

Other detailed matters of the embodiments are included in the detailed description and the drawings.

According to the present disclosure, it is possible to reduce the folding stress in the folding area of the display device.

According to the present disclosure, it is possible to minimize or at least reduce the occurrence of wrinkles by suppressing the sagging of the display panel in the folding area of the display device.

The display device of the present disclosure may maintain excellent appearance quality and durability.

The effects according to the present disclosure are not limited to the contents exemplified above, and more various effects are included in the present disclosure.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a schematic plan view of a display device according to one or more embodiments of the present disclosure.

FIG. 2 is a cross-sectional view illustrating an example taken along a cutting line I-I′ of FIG. 1.

FIGS. 3A to 3E are process diagrams for explaining a method of manufacturing a display device according to one or more embodiments of the present disclosure.

FIG. 4 is a schematic cross-sectional view for explaining an example of a cross-sectional structure of a display device according to one or more other embodiments of the present disclosure.

FIGS. 5A to 5F are process diagrams for explaining a method of manufacturing a display device according to one or more other embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present disclosure will be described in detail with reference to accompanying drawings.

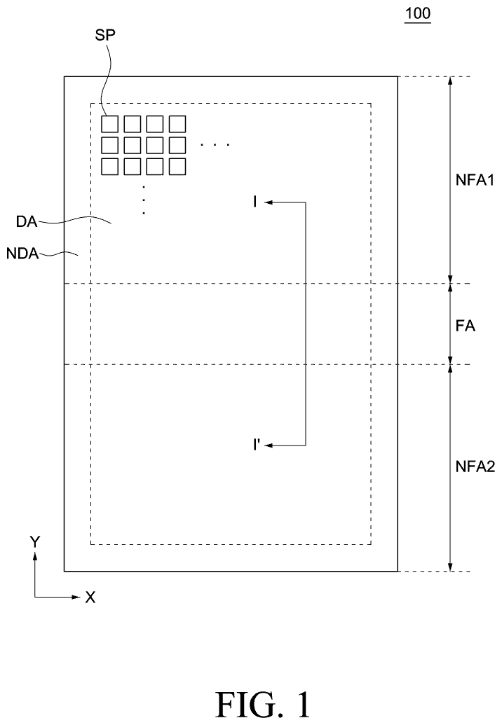

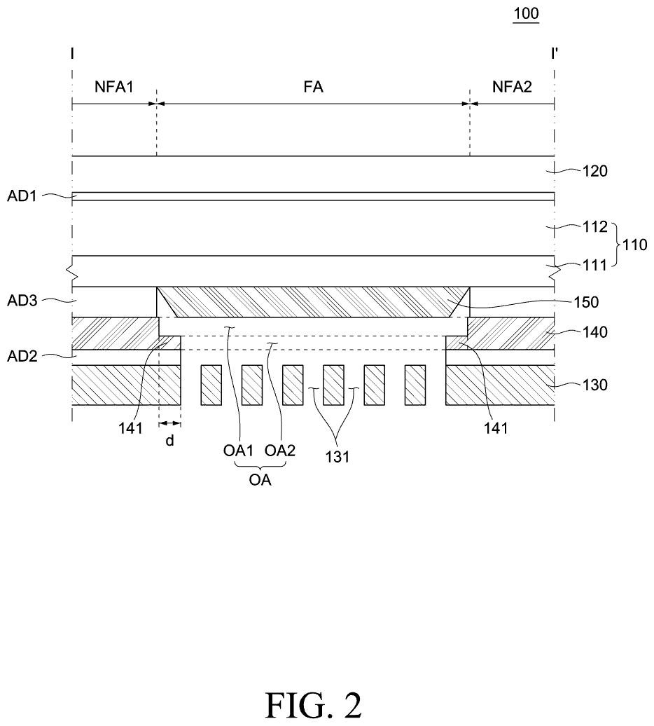

FIG. 1 is a schematic plan view of a display device according to one or more embodiments of the present disclosure. FIG. 2 is a cross-sectional view illustrating an example taken along a cutting line I-I′ of FIG. 1.

Referring to FIGS. 1 and 2 together, a display device 100 according to one or more embodiments of the present disclosure includes a display panel 110, a cover member 120, a first support substrate 130, a second support substrate 140, and a support member 150. Hereinafter, for convenience of description, it is assumed that the foldable display device 100 according to one or more embodiments of the present disclosure is an organic light emitting display device, but it is not limited thereto.

First, referring to FIG. 1, the display panel 110 may include a display area DA and a non-display area NDA. Further, the display panel 110 includes a folding area FA and non-folding areas NFA1 and NFA2. The display panel 110 may be divided into a display area DA and a non-display area NDA depending on whether an image is displayed. Further, the display panel 110 may be divided into a folding area FA and non-folding areas NFA1 and NFA2 depending on whether to be folded. Accordingly, a partial area of the display panel 110 may be the display area DA and the folding area FA and the other partial area of the display panel 110 may be the non-display area NDA and the non-folding areas NFA1 and NFA2.

Meanwhile, hereinafter, for convenience of description, it is assumed that the display device 100 according to one or more embodiments of the present disclosure is a foldable display device in which one folding area FA is disposed only in a partial area of the display area DA. However, the display device 100 according to one or more embodiments of the present disclosure may be a display device in which a plurality of folding areas is disposed in the display area DA of the display panel 110, but is not limited thereto.

The display area DA is an area in which a plurality of pixels are disposed and an image is substantially displayed. In the display area DA, a plurality of pixels including an emission area for displaying an image, a thin film transistor for driving the pixels, and a capacitor, and the like may be disposed. One pixel may include a plurality of sub pixels SP. The sub-pixels SP are minimum units constituting the display area, and each sub-pixel SP may be configured to emit light of a specific wavelength band. For example, each sub pixel SP may be configured to emit red light, green light, blue light, or white light.

The non-display area NDA is disposed to surround the display area DA. The non-display area NDA is an area where an image is not substantially displayed and various line lines, driving ICs, and the like for driving pixels and driving elements disposed in the display area DA are disposed.

The display panel 110 may be defined as a folding area FA and non-folding areas NFA1 and NFA2 depending on whether to be folded. The display panel 110 includes one folding area FA which is foldable and non-folding areas NFA1 and NFA2 excluding the folding area FA. The folding area FA is an area that is folded when the foldable display device 100 is folded and may be folded according to a specific radius of curvature with respect to a folding axis. Here, the folding axis may be formed in the X-axis direction. The non-folding areas NFA1 and NFA2 may be located on both sides of the folding area FA along the folding direction. Here, the folding direction may mean a Y-axis direction perpendicular to the folding axis. When the folding area FA is folded with respect to the folding axis, the folding area FA may form a part of a circle or an oval. In this case, the radius of curvature of the folding area FA refers to a radius of a circle or an oval formed by the folding area FA.

The non-folding areas NFA1 and NFA2 are areas that are not folded when the display device 100 is folded. That is, the non-folding areas NFA1 and NFA2 maintain a flat state when the display device 100 is folded. The non-folding areas NFA1 and NFA2 may extend from both sides of the folding area FA along the folding direction. In this case, the folding area FA may be defined between the non-folding areas NFA1 and NFA2. The non-folding areas NFA1 and NFA2 include a first non-folding area NFA1 and a second non-folding area NFA2. The first non-folding area NFA1 may extend from one side of the folding area FA, and the second non-folding area NFA2 may extend from the other side of the folding area FA. When the display device 100 is folded with respect to the folding axis, the first non-folding area NFA1 and the second non-folding area NFA2 may overlap each other.

The display panel 110 includes a base substrate 111 and a display part 112 disposed on the base substrate 111 and including a driving thin film transistor, a display element, and the like. In the display panel 110, a base substrate 111 on which a display part 112 including a driving thin film transistor and a display element is formed may be encapsulated by an encapsulation part.

The display panel 110 includes a thin base substrate 111 to implement flexibility.

The base substrate 111 supports various elements constituting the display panel 110. The base substrate 111 may be formed of an insulating material having a very thin thickness to implement flexibility. For example, the base substrate 111 may be an insulating substrate including polyimide. However, the present disclosure is not limited thereto, and the base substrate 111 may further include one or more selected from polyethersulfone, polyethylene terephthalate, and polycarbonate.

A driving thin film transistor for driving the display element may be disposed on the base substrate 111. The driving thin film transistor may be disposed in each of the plurality of pixels. For example, the driving thin film transistor may include a gate electrode, an active layer, a source electrode, and a drain electrode. Further, the driving thin film transistor may further include a gate insulating layer which insulates the gate electrode from the active layer and an interlayer insulating layer which insulates the gate electrode from the source electrode and the drain electrode.

The display element may be an organic light emitting element. The organic light emitting element may include an anode, a cathode, and an organic light emitting layer disposed therebetween. In the organic light emitting device, holes injected from the anode and electrons injected from the cathode are combined in the organic emission layer to emit light. An image may be displayed using the light emitted as described above. However, the present disclosure is not limited thereto, and the display element may be an inorganic light emitting element.

The cover member 120 may be disposed on the display panel 110. The cover member 120 may be implemented as a cover based on flexible plastic that may be folded for thinness and flexibility of the display device 100. For example, the cover member 120 may be a film made of a polymer such as polyimide, polyamide imide, polyethylene terephthalate, polymethyl methacrylate, polypropylene glycol, and polycarbonate. Alternatively, the cover member 120 may be a film made of a photoisotropic polymer such as a cycloolefin (co) polymer, photoisotropic polycarbonate, or photoisotropic polymethyl methacrylate.

The cover member 120 may have a multilayer structure in which various functional layers are stacked. For example, the cover member 120 may include various functional layers such as an external light reflection reducing layer, a UV blocking layer, and a hard coating layer. In addition, a touch panel constituting a touch sensor may be selectively disposed between the display panel 110 and the cover member 120 as necessary.

A first adhesive layer AD1 may be disposed between the display panel 110 and the cover member 120. The first adhesive layer AD1 may be used to fix the cover member 120 onto the display panel 110. For example, the first adhesive layer AD1 may include one or more selected from optical clear adhesive (OCA), optical clear resin (OCR), and pressure sensitive adhesive (PSA), but is not limited thereto.

The first support substrate 130 may be referred to as a plate bottom or a bottom plate. The first support substrate 130 may be a plate that is foldable and has excellent rigidity. The first support substrate 130 may be formed of a material having rigidity greater than that of the base substrate 111 to support the display panel 110.

The first support substrate 130 may be made of a metal material such as stainless steel (SUS), stainless steel (SUS) containing metal such as nickel (Ni), iron (Fe), aluminum (Al), or magnesium (Mg). Preferably, stainless steel (SUS) may be applied as the first support substrate 130. For example, the stainless steel (SUS) has a high restoring force and rigidity so that the high rigidity may be maintained even when the thickness of the first support substrate 130 is reduced. Therefore, the first support substrate 130 may reduce the curvature radius of the folding area FA by reducing the overall thickness of the display device 100 while supporting the display panel 110. However, the first support substrate 130 is not limited thereto and may be formed of a polymer such as polymethylmetacrylate (PMMA), polycarbonate (PC), polyvinylalcohol (PVA), acrylonitrile-butadiene-styrene (ABS), polyethylene terephthalate (PET), silicone, or polyurethane (PU).

The first support substrate 130 includes a plurality of opening patterns 131 formed to correspond to the folding area FA of the display device 100. The display device 100 may be folded or unfolded by increasing the elastically deformed section by the plurality of opening patterns 131 formed in the folding area FA. In FIG. 2, seven opening patterns 131 are formed for convenience of description, but are not limited thereto.

The plurality of opening patterns 131 may be formed on the first support substrate 130 so as to correspond to the folding area FA. That is, the plurality of opening patterns 131 may be holes formed by penetrating the first support substrate 130 in the thickness direction. When the display device 100 is folded, stress is concentrated in the folding area FA. The plurality of opening patterns 131 may disperse the stress concentrated on the folding area FA during the folding. As described above, the plurality of opening patterns 131 is formed at a position corresponding to the folding area FA so that the folding of the display device 100 is easy and the resilience is excellent.

Each of the plurality of opening patterns 131 may be formed to extend long along a direction parallel to the folding axis. That is, each of the plurality of opening patterns 131 may be formed to extend long along the same direction as the folding axis. Accordingly, each of the plurality of opening patterns 131 may be formed in parallel with the folding axis in the form of a bar on a plan view. Meanwhile, each of the plurality of opening patterns 131 may continuously extend to the non-display area across the display area FA without being disconnected in the same direction as the folding axis, but is not limited thereto.

The second support substrate 140 is disposed on the first support substrate 130. The second support substrate 140 may be referred to as a plate top or a top plate. The second support substrate 140 may enhance the rigidity of the display panel 110 and suppress the visibility of the plurality of opening patterns 131 formed in the first support substrate 130 through the display panel 110.

The second support substrate 140 includes a first opening OA corresponding to the folding area FA. The first opening OA may include an upper area OA1 and a lower area OA2 having different widths. As such, the second support substrate 140 may be spaced apart from each other with the first opening OA interposed therebetween. The side surface of the second support substrate 140 may be exposed by the first opening OA in the folding area FA.

A width of the upper area OA1 of the first opening OA may be greater than a width of the lower area OA2. Positions of the side surfaces of the second support substrate 140 exposed by the first opening OA may be different from each other in the upper area OA1 and the lower area OA2.

For example, the second support substrate 140 corresponding to the lower area OA2 of the first opening OA may include a protrusion 141 protruding toward the first opening OA. The protrusion 141 may be an area in which the second support substrate 140 protrudes toward the first opening OA in an area corresponding to the lower area OA2 of the first opening OA. Therefore, a side surface corresponding to the lower area OA2, among the side surfaces of the second support substrate 140 exposed by the first opening OA, may be located inside the first opening OA rather than a side surface corresponding to the upper area OA1. As such, the side surface of the second support substrate 140 exposed by the first opening OA may form a step.

The protruding length d of the protrusion 141 may be 0.1 μm to 0.5 μm or less. When the protruding length d of the protrusion 141 satisfies the above range, interference between the support member 150 and the second support substrate 140 may be prevented from occurring in the folding area FA during the folding of the display device 100. Accordingly, damage to the display panel 110 that may occur due to interference between the support member 150 and the second support substrate 140 may be prevented.

In the meantime, even though in the drawing, it is illustrated that the second support substrate 140 has a thickness similar to that of the first support substrate 130, it is not limited thereto. That is, the second support substrate 140 may have a thickness thinner than that of the first support substrate 130. In this case, the second support substrate 140 may be made of stainless steel (SUS), stainless steel (SUS) containing metal such as nickel (Ni), or a metal material such as iron (Fe), aluminum (Al), or magnesium (Mg). Further, the second support substrate 140 is not limited thereto and may be made of a polymer such as polymethylmethacrylate (PMMA), polycarbonate (PC), polyvinyl alcohol (PVA), acrylonitrile-butadiene-styrene (ABS), polyethylene terephthalate (PET), silicone, or polyurethane PU. In addition, the second support substrate 140 may be formed of the same material as the first support substrate 130, but is not limited thereto.

A second adhesive layer AD2 may be disposed between the first support substrate 130 and the second support substrate 140. The second adhesive layer AD2 may serve to bond the first support substrate 130 and the second support substrate 140. The second adhesive layer AD2 may include a second opening in an area corresponding to the first opening OA in the folding area FA. In this case, the second opening may correspond to a lower area OA2 of the first opening OA. For example, a width of the second opening may be the same as a width of the lower area OA2 of the first opening OA, but is not limited thereto. For example, the second adhesive layer AD2 may include one or more selected from optical clear adhesive (OCA), optical clear resin (OCR), and pressure sensitive adhesive (PSA), but is not limited thereto.

The second support substrate 140 may be bonded to the base substrate 111 of the display panel 110 through the third adhesive layer AD3. The third adhesive layer AD3 may include a third opening corresponding to the first opening OA. Accordingly, at least a part of the third adhesive layer AD3 may be spaced apart from each other by the third opening in the folding area FA. The third opening of the third adhesive layer AD3 may correspond to the upper area OA1 of the first opening OA of the second support substrate 140. For example, a width of the third opening of the third adhesive layer AD3 may be equal to a width of the upper area OA1 of the first opening OA of the second support substrate 140. For example, the third adhesive layer AD3 may include one or more selected from optical clear adhesive (OCA), optical clear resin (OCR), and pressure sensitive adhesive (PSA), but is not limited thereto.

The support member 150 is disposed at a position corresponding to the first opening OA1 of the second support substrate 140 below the base substrate 111. The support member 150 may be disposed below the base substrate 111 at a position corresponding to the folding area FA. For example, the support member 150 may be disposed at a position corresponding to the first opening OA of the second support substrate 140. Accordingly, at least a part of the lower surface of the support member 150 may overlap the first opening OA. Meanwhile, in order to prevent the display panel from sagging in the folding area and improve rigidity, a distance from the lower surface of the support member 150 to the upper surface of the first support substrate 130 may be 0.01 mm to 0.03 mm.

The support member 150 may be made of a material having a larger modulus than that of the base substrate 111, and in the display device 100 according to one or more embodiments of the present disclosure, the support member 150 may be glass. Therefore, when the display device 100 is folded, the support member 150 of the display panel 110 may serve to support the display panel 110 below the base substrate 111.

The support member 150 may be disposed on the same layer as the third adhesive layer AD3. Accordingly, the support member 150 may be in direct contact with the lower surface of the base substrate 111 without a separate adhesive layer. The support member 150 may be disposed in the third opening of the third adhesive layer AD3. In this case, the third adhesive layer AD3 may be disposed to surround the support member 150.

The maximum thickness of the support member 150 may be 0.03 mm to 0.05 mm. For example, the thickness of the support member 150 may be smaller than the thickness of the third adhesive layer AD3. In this case, a thickness difference between the support member 150 and the third adhesive layer AD3 may be 0.02 μm or less. As described above, when the thickness of the support member 150 satisfies the above-described range, interference generated between the support member 150 and the second support substrate 140 may be more effectively prevented. Accordingly, damage to the display panel 110 that may occur due to interference between the support member 150 and the second support substrate 140 may be prevented.

Alternatively, the support member 150 may have the same thickness as the third adhesive layer AD3. In this case, while preventing interference between the support member 150 and the second support substrate 140 in the folding area FA, the support member 150 may more effectively support the display panel 110 in the folding area FA.

The support member 150 may have a shape whose width decreases toward the bottom. The side surface of the support member 150 may be an inclined surface inclined toward the inside of the support member 150 toward the bottom. A width of the upper surface of the support member 150 may be larger than a width of the lower surface of the support member 150. A width of the upper surface of the support member 150 may be equal to a width of the upper area OA1 of the opening OA of the second support substrate 140. Alternatively, a width of the upper surface of the support member 150 may be smaller than a width of the upper area OA1 of the opening OA of the second support substrate 140. In this case, at least a portion of the support member 150 may overlap the protrusion 141 of the second support substrate 140.

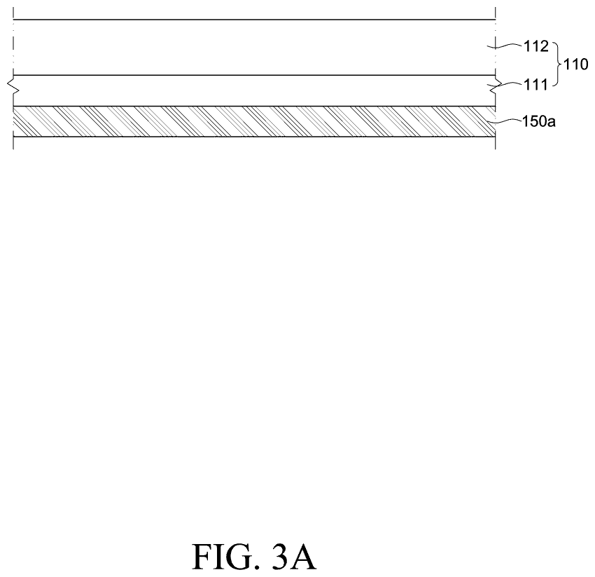

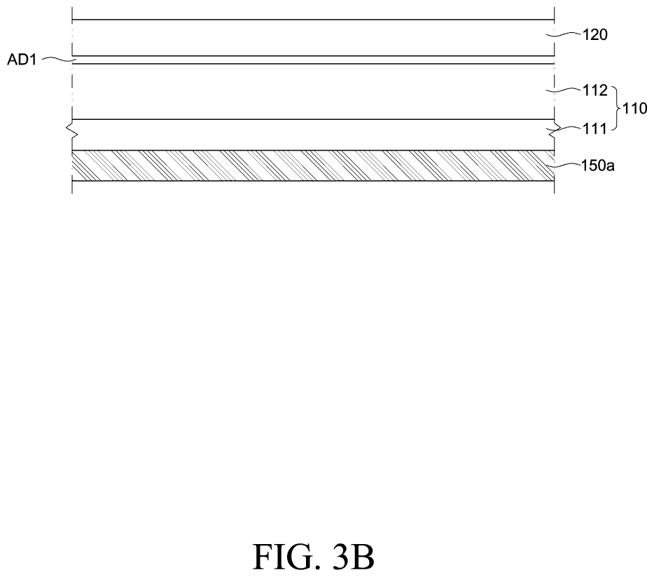

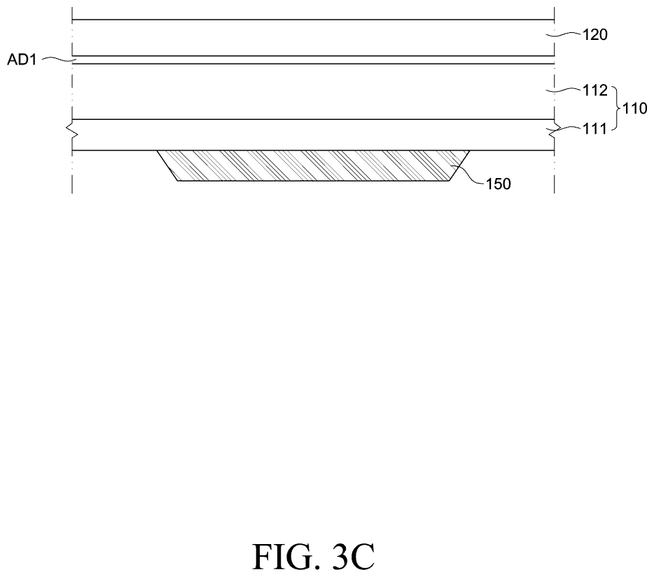

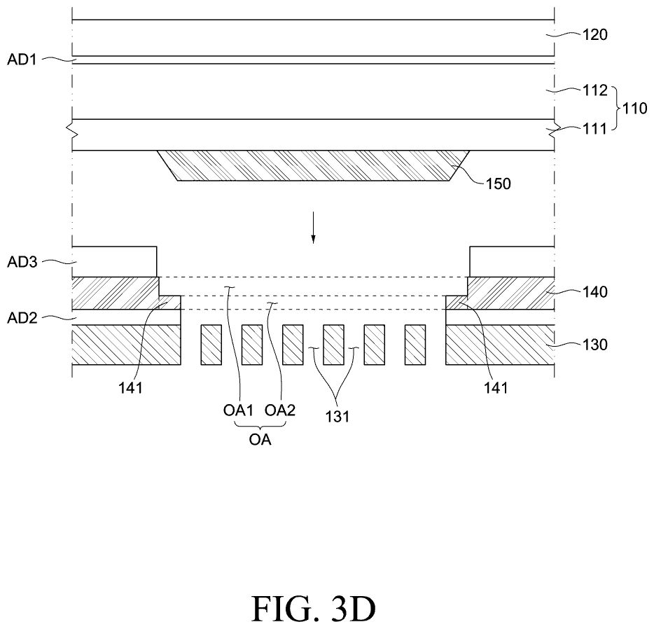

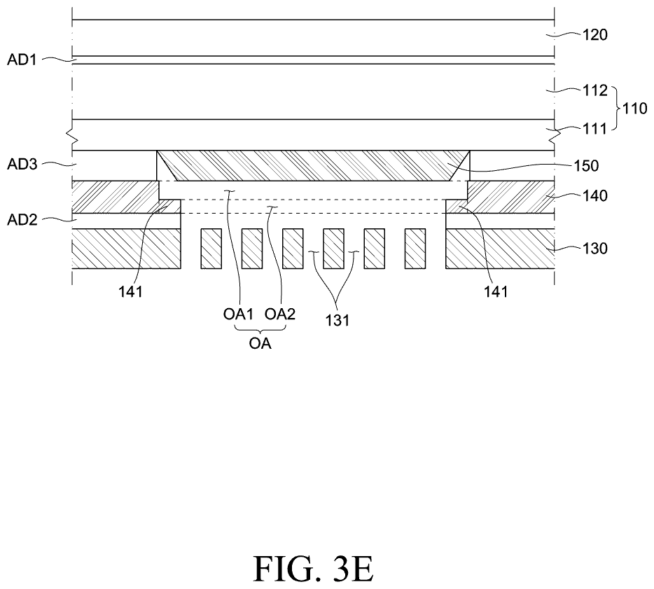

FIGS. 3A to 3E are process diagrams for explaining a method of manufacturing a display device according to one or more embodiments of the present disclosure.

Referring to FIGS. 3A and 3B together, the base substrate 111 is formed on the transfer substrate 150a. The transfer substrate 150a supports the base substrate 111 formed thereon. For example, the transfer substrate 150a may be a glass substrate. The base substrate 111 is used in the form of a film which is relatively thinner than the transfer substrate 150a, and accordingly, sagging may occur during the manufacturing process and handling is difficult. Since the glass substrate is thick and has a large rigidity, the base substrate 111 is supported so that the process can be easily performed. In this case, the base substrate 111 may be directly deposited on the transfer substrate 150a without a separate adhesive layer. Next, a display part 112 in which a transistor, a light emitting element, and the like are encapsulated is formed on the base substrate 111. Next, the first adhesive layer AD1 is applied on the display part 112 and the cover member 120 is bonded onto the first adhesive layer AD1.

Referring to FIG. 3C, the support member 150 is formed in the folding area FA by etching and removing a portion of the transfer substrate 150a corresponding to the folding area FA. As described above, in an area other than the folding area FA, the transfer substrate 150a is removed so that the lower surface of the base substrate 111 may be exposed. At least a part of the side surfaces of the support member 150 may be etched such that the width of the support member 150 becomes narrower toward the opposite surface of the surface in contact with the base substrate 111. Accordingly, at least a part of the side surface of the support member 150 is formed to include an inclined surface inclined toward the inside of the support member 150 to provide a first configuration.

Referring to FIG. 3D, a first support substrate 130 having an opening pattern 131 formed in at least a portion thereof is provided. On one surface of the first support substrate 130, the second adhesive layer AD2 is applied to the outer periphery of the area in which the opening pattern 131 is formed. The second support substrate 140 including the first opening OA is bonded to at least a portion of the applied second adhesive layer AD2. In this case, the second support substrate 140 may be manufactured in a shape including a protrusion 141 protruding at least partially in the first opening OA. Therefore, the area of the upper area OA1 of the first opening OA formed on the upper surface of the second support substrate 140 may be larger than the area of the lower area OA2 of the first opening OA formed on the lower surface of the second support substrate 140. A lower surface of the second support substrate 140, which is formed to have a small area of the first opening OA, is bonded to be in contact with the second adhesive layer AD2. Next, a second configuration is provided by applying the third adhesive layer AD3 to the upper surface of the second support substrate 140.

Further, as shown in FIG. 3E, the third adhesive layer AD3 of the second configuration and the bottom surface of the exposed base substrate 111 of the first configuration provided in FIG. 3C are bonded to each other to complete the display device 100 according to one or more embodiments of the present disclosure.

Meanwhile, a foldable display device in which at least a part of a substrate is folded uses a flexible substrate having relatively weak rigidity compared to a metal substrate. Accordingly, it may be difficult to maintain a constant shape of the flexible substrate during folding, and sagging may occur due to various components formed thereon. In this way, when the flexible substrate is sagging, wrinkles occur in the folding area, which may interfere with viewing the content by being visually recognized by the user.

Accordingly, in the display device 100 according to one or more embodiments of the present disclosure, the support member 150 is disposed below the base substrate 111 in the folding area FA. As described above, the separate support member 150 is disposed in the folding area FA to reinforce the rigidity of the base substrate 111 in the folding area FA. Accordingly, a sagging phenomenon of the display panel 110 occurring in the folding area FA may be suppressed. Further, by suppressing the sagging of the display panel 110, it is possible to suppress the appearance of wrinkles in the folding area FA from being visually recognized. Accordingly, the display device 100 according to one or more embodiments of the present disclosure may have improved appearance quality.

Further, the display device 100 according to one or more embodiments of the present disclosure includes the opening OA in the second support substrate 140 in the area corresponding to the support member 150. Therefore, when the display device 100 is folded, interference between the support member 150 and the second support substrate 140 may be prevented. Accordingly, damage to the display panel 110 that may occur due to interference between the support member 150 and the second support substrate 140 may be prevented.

As described above, in the display device 100 according to one or more embodiments of the present disclosure, the configuration disposed below the support member 150 in the folding area FA may be simplified. When various configurations including the second support substrate 140 and the like are disposed in the folding area FA, all configurations disposed in the folding area FA are folded together during the folding of the display device 100 so that stress applied to all configurations including the display panel 110 may increase. In particular, in the case of the display panel 110 disposed relatively above, the degree of folding is greater than that of the first support substrate 130 disposed at the outside, so that stronger stress may be applied. In contrast, in the display device 100 according to one or more embodiments of the present disclosure, the configuration disposed below the display panel 110 in the folding area FA is simplified so that the radius of curvature of the display panel 110 during the folding may be relatively reduced. Accordingly, stress acting on the display panel 110 may be reduced. Accordingly, the durability of the display device 100 according to one or more embodiments of the present disclosure may be improved.

Hereinafter, a stress reducing effect of the display device 100 according to one or more embodiments of the present disclosure will be described through a simulation experiment result.

First, in order to confirm the stress reduction effect in the folding area FA according to the presence or absence of the support member 150, a structure in which a base substrate (polyimide, 16 μm), a display part (22 μm) including a light emitting element, first adhesive layers (OCA, 25 μm), a polarizing plate (38 μm), second adhesive layers (OCA, 25 μm), a cover glass (30 μm), a third adhesive layer (OCA, 20 μm), and a polyimide film (50 μm) are sequentially laminated was prepared, and this was used as a comparative example.

In the structure of the comparative example, the support member (150, glass) were directly deposited under the base substrate 111 to prepare an example. At this time, Embodiments 1 to 3 were prepared by varying the thickness of the support member 150. Further, the thickness of the support member 150 applied to each example is described in Table 1 below. When the display devices of the comparative example and examples prepared as described above are completely folded, the total stress and the tensile stress generated in the folding area are measured, respectively, and the results thereof are described in Table 1 below.

TABLE 1

| | Thickness (μm) of | Total | Tensile |
|---|---|---|---|
| | a support member | stress (MPa) | stress (MPa) |
| Comparative | — | 115.8. | 99.84 |
| example | | | |
| Embodiment 1 | 10 | 110.4 | 94.07 |
| Embodiment 2 | 20 | 111.1.1. | 94.69. |
| Embodiment 3 | 30 | 111.9. | 95.42. |

Referring to Table 1, in the display devices of Embodiments 1 to 3, it was confirmed that the total stress and tensile stress acting on the folding area were reduced compared to the comparative example.

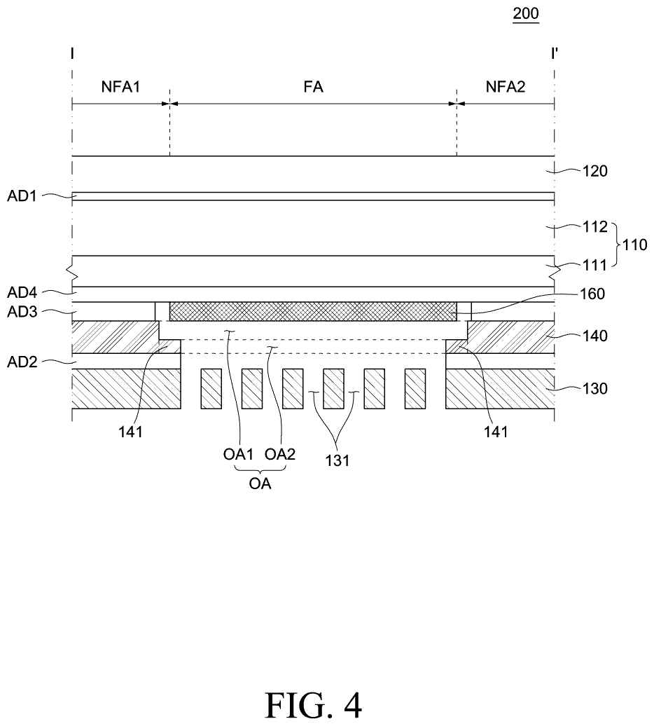

FIG. 4 is a schematic cross-sectional view for explaining an example of a cross-sectional structure of a display device according to one or more other embodiments of the present disclosure. A display device 200 of FIG. 4 has the substantially same configurations as the display device 100 of FIGS. 1 to 3, except for a support member 160 and a fourth adhesive layer AD4, so that a redundant description will be omitted.

In the display device 200 according to one or more other embodiments of the present disclosure, the support member 160 may be a polymer film. Specifically, the support member 160 may be a polymer film having a larger modulus than the base substrate 111 of the display panel PN. Accordingly, the support member 160 may stably support the display panel PN in the folding area FA.

For example, the support member 160 may include a polymer such as polymethylmetacrylate (PMMA), polycarbonate (PC), polyvinylalcohol (PVA), acrylonitrile-butadiene-styrene (ABS), polyethylene terephthalate (PET), silicone, or polyurethane (PU), but is not limited thereto.

The support member 160 may be disposed under the display panel PN so as to correspond to the folding area FA. Further, under the display panel PN, the third adhesive layer AD3 may be disposed on the same layer as the support member 160. In this case, the third adhesive layer AD3 may be disposed to surround the outer periphery of the support member 160. The support member 160 and the third adhesive layer AD3 may be spaced apart from each other, but are not limited thereto.

A fourth adhesive layer AD4 may be further disposed between the display panel PN and the support member 160. The fourth adhesive layer AD4 may serve to bond the display panel PN to the support member 160. The fourth adhesive layer AD4 may be disposed on the entire bottom surface of the display panel PN. Therefore, the fourth adhesive layer AD4 may be in contact with the third adhesive layer AD3. That is, the third adhesive layer AD3 and the support member 160 may be disposed to contact the bottom surface of the fourth adhesive layer AD4.

A thickness of the support member 160 may be the same as a thickness of the third adhesive layer AD3. Alternatively, a thickness of the support member 160 may be less than a thickness of the third adhesive layer AD3. For example, the maximum thickness of the support member 150 may be 0.03 mm to 0.05 mm. Further, a thickness difference between the support member 160 and the third adhesive layer AD3 may be 0.02 μm or less. Therefore, when the thickness difference between the support member 160 and the third adhesive layer AD3 exceeds 0.02 μm, the thickness of the support member 160 becomes too thin, making it difficult to stably support the display panel PN.

A width of the bottom surface of the support member 160 may be smaller than a width of the first opening OA1. Further, a width of the bottom surface of the support member 160 may be larger than a width of the second opening OA2. Therefore, the end of the support member 160 may overlap the protrusion 141 of the second support substrate 140.

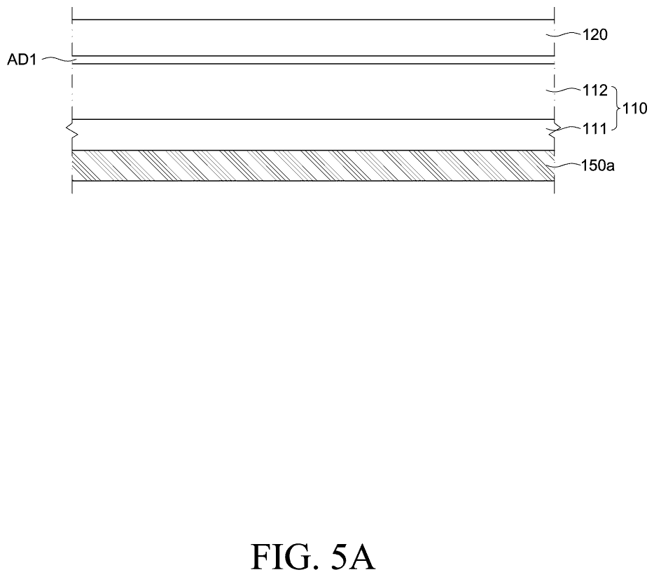

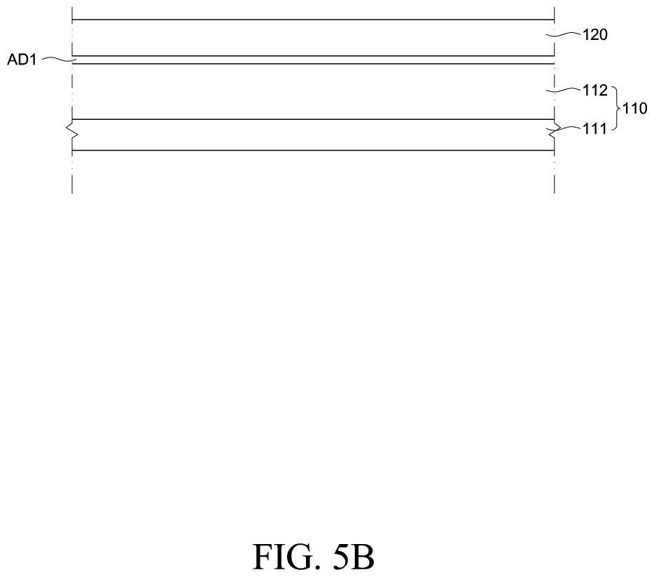

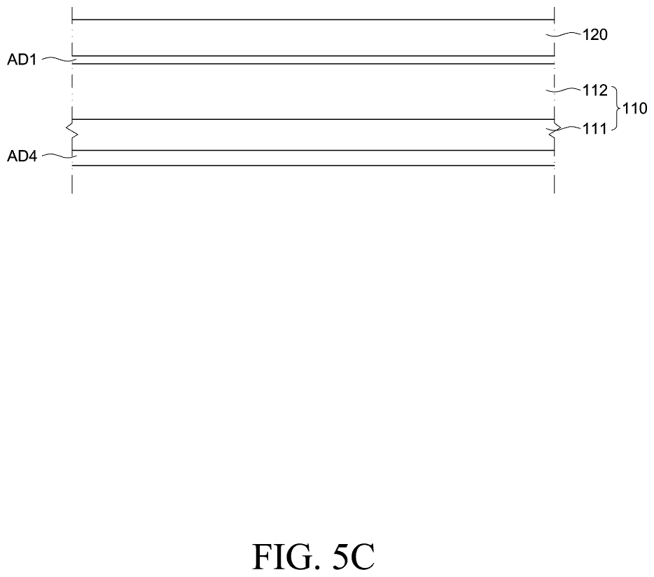

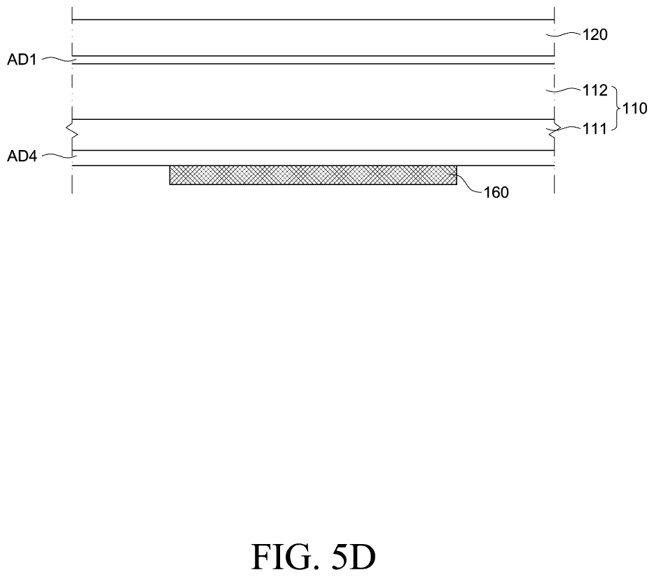

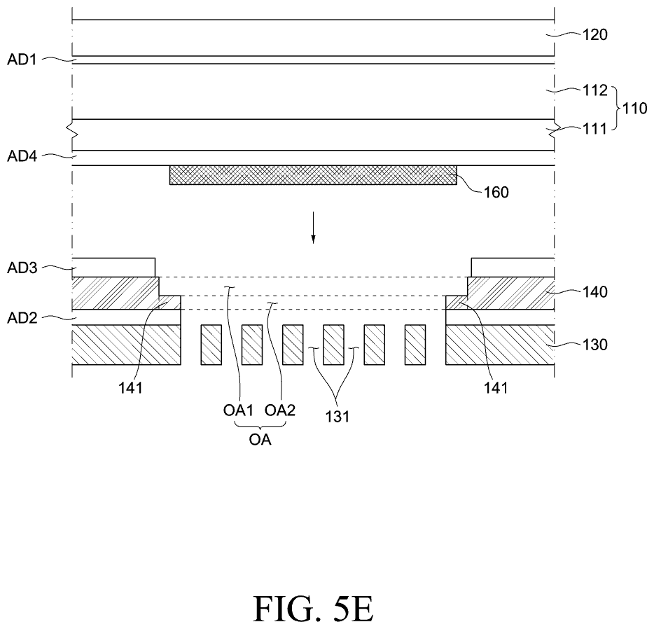

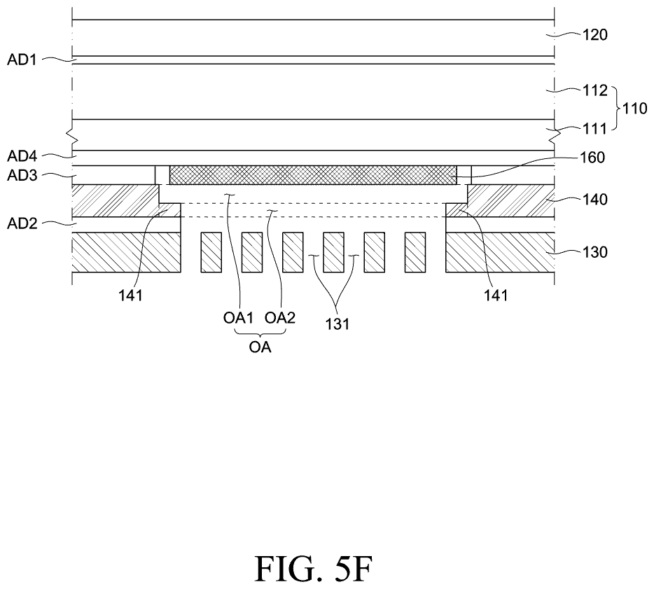

FIGS. 5A to 5F are process diagrams for explaining a method of manufacturing a display device according to one or more other embodiments of the present disclosure.

Referring to FIG. 5A, a base substrate 111 is formed on a transfer substrate 150a. The transfer substrate 150a supports the base substrate 111 formed thereon. For example, the transfer substrate 150a may be a glass substrate. The base substrate (111) is used in the form of a film which is relatively thinner than the transfer substrate (150a), and accordingly, sagging may occur during the manufacturing process and handling is difficult. Since the glass substrate is thick and has a large rigidity, the base substrate (111) is supported so that the process can be easily performed. In this case, although not illustrated in the drawings, a sacrificial layer may be further disposed between the base substrate 111 and the transfer substrate 150a.

Next, a display part 112 in which a transistor, a light emitting element, and the like are encapsulated is formed on the base substrate 111. Next, the first adhesive layer AD1 is applied on the display part 112 and the cover member 120 is bonded onto the first adhesive layer AD1.

Referring to FIG. 5B, the transfer substrate 150a is removed from the base substrate 111. In this case, even though it is not illustrated in the drawing, a sacrificial layer is further disposed between the base substrate 111 and the transfer substrate 150a so that the transfer substrate 150a may be more easily removed from the base substrate 111.

Referring to FIGS. 5C and 5D together, a material for forming the fourth adhesive layer AD4 is applied to a lower surface of the exposed base substrate 111 by removing the transfer substrate 150a to form the fourth adhesive layer AD4. Further, the support member 160, which is a polymer film, is bonded to the lower surface of the fourth adhesive layer AD4. In this case, the support member 160 is selectively disposed only in an area corresponding to the folding area FA. That is, the support member 160 is disposed only on a part of the bottom surface of the fourth adhesive layer AD4. In this way, the first configuration is prepared.

Next, referring to FIG. 5E, a first support substrate 130 having an opening pattern 131 formed in at least a portion thereof is provided. On one surface of the first support substrate 130, the second adhesive layer AD2 is applied to the outer periphery of the area in which the opening pattern 131 is formed. The second support substrate 140 including the first opening OA is bonded to at least a portion of the applied second adhesive layer AD2. In this case, the second support substrate 140 may be manufactured in a shape including a protrusion 141 protruding at least partially in the first opening OA. Therefore, the area of the upper area OA1 of the first opening OA formed on the upper surface of the second support substrate 140 may be larger than the area of the lower area OA2 of the first opening OA formed on the lower surface of the second support substrate 140. A lower surface of the second support substrate 140, which is formed to have a small area of the first opening OA, is bonded to be in contact with the second adhesive layer AD2. Next, a second configuration is provided by applying the third adhesive layer AD3 to the upper surface of the second support substrate 140.

Further, as shown in FIG. 5E, the third adhesive layer AD3 of the second configuration and the bottom surface of the fourth adhesive layer AD4 exposed among the first configurations provided in FIG. 5D are bonded to each other. Accordingly, as shown in FIG. 5F finally, the display device 200 according to one or more other embodiments of the present disclosure may be completed.

In the display device 200 according to one or more other embodiments of the present disclosure, the support member 160 is disposed below the base substrate 111 in the folding area FA to reinforce the rigidity of the base substrate 111 in the folding area FA. Accordingly, the sagging phenomenon of the display panel 110 occurring in the folding area FA may be further suppressed, and the visible appearance of wrinkles in the folding area FA may be further suppressed. Accordingly, the display device 200 according to one or more other embodiments of the present disclosure may further improve appearance quality.

Further, in the display device 200 according to one or more other embodiments of the present disclosure, the opening OA is included in the second support substrate 140 in the area corresponding to the support member 160 so that when the display device 200 is folded, interference between the support member 150 and the second support substrate 140 may be prevented. Accordingly, damage to the display panel 110 that may occur due to interference between the support member 150 and the second support substrate 140 may be prevented.

Further, in the display device 200 according to one or more other embodiments of the present disclosure, the configuration disposed below the display panel 110 in the folding area FA is simplified so that the radius of curvature of the display panel 110 during the folding may be relatively reduced. Accordingly, stress acting on the display panel 110 may be reduced. Accordingly, the durability of the display device 200 according to one or more other embodiments of the present disclosure may be further improved.

The embodiments of the present disclosure can also be described as follows:

A display device according to one or more embodiments of the present disclosure comprises a display panel including a folding area and non-folding areas positioned at both sides of the folding area and including a base substrate and a display part disposed on the base substrate, a first support substrate configured to support the display panel from a lower portion of the display panel and including a plurality of opening patterns corresponding to the folding area, a second support substrate disposed between the display panel and the first support substrate and including an opening corresponding to the folding area, and a support member disposed under the base substrate and disposed to correspond to the opening.

The support member may be glass.

The support member may have a smaller width toward the bottom.

The support member may be in direct contact with the lower surface of the base substrate.

The support member may be a polymer film having a larger modulus than that of the base substrate.

The display device may further include a first adhesive layer disposed between the polymer film and the base substrate.

The thickness of the support member may be 0.03 mm to 0.05 mm.

The base substrate may include polyimide.

The display device may further include a second adhesive layer disposed between the base substrate and the second support substrate, and the second adhesive layer may be disposed to surround the support member.

The thickness of the support member and the thickness of the second adhesive layer may be the same.

The thickness of the support member may be smaller than the thickness of the second adhesive layer.

The difference in thickness between the support member and the second adhesive layer may be 0.02 μm or less.

The opening may include an upper region and a lower region having different widths, and a width of the upper region of the opening may be greater than a width of the lower region.

The second support substrate may include a protrusion protruding toward the lower area of the opening.

The protruding length of the protrusion may be 0.5 μm or less, and the protrusion may overlap at least a portion of the support member.

The distance from the lower surface of the support member to the upper surface of the first support substrate may be 0.01 mm to 0.03 mm.

A display device according to one or more other embodiments of the present disclosure includes a display panel including a folding area and non-folding areas positioned at both sides of the folding area and including a base substrate and a display part disposed on the base substrate, a support member disposed below the display panel and disposed to correspond to the folding area, a first adhesive layer disposed below the display panel and disposed to surround the support member, a first support substrate disposed below the first adhesive layer and including a first opening corresponding to the support member, a second adhesive layer disposed below the first support substrate and including a second opening corresponding to the support member, and a second support substrate disposed below the second adhesive layer and including a plurality of opening patterns corresponding to the folding area.

The support member may be glass, and the support member may have a narrower width toward the bottom, and the support member and the first adhesive layer may be in direct contact with the bottom surface of the base substrate.

The support member may be a polymer film, and the display device may further include a third adhesive layer disposed between the base substrate and the polymer film, and the support member and the first adhesive layer may be in direct contact with a lower surface of the third adhesive layer.

The first opening may include an upper region and a lower region having different widths, and a width of the upper region may be greater than a width of the lower region.

Although the embodiments of the present disclosure have been described in detail with reference to the accompanying drawings, the present disclosure is not limited thereto and may be embodied in various forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a display panel including a folding area and non-folding areas positioned on both sides of the folding area, the non-folding areas including a base substrate and a display part disposed on the base substrate;
a first support substrate configured to support the display panel from a lower portion of the display panel, the first support substrate including a plurality of opening patterns corresponding to the folding area;
a second support substrate disposed between the display panel and the first support substrate, the second support substrate including an opening corresponding to the folding area; and
a support member disposed under the base substrate and disposed to correspond to the opening.

2. The display device according to claim 1, wherein the support member is glass.

3. The display device according to claim 2, wherein a width of the support member is smaller toward a bottom of the support member.

4. The display device according to claim 2, wherein the support member is in direct contact with a lower surface of the base substrate.

5. The display device according to claim 1, wherein the support member is a polymer film having a modulus larger than a modulus of the base substrate.

6. The display device according to claim 5, further comprising a first adhesive layer disposed between the polymer film and the base substrate.

7. The display device according to claim 1, wherein a thickness of the support member is 0.03 mm to 0.05 mm.

8. The display device according to claim 1, wherein the base substrate includes polyimide.

9. The display device according to claim 2, further comprising:
a second adhesive layer disposed between the base substrate and the second support substrate,
wherein the second adhesive layer is disposed to surround the support member.

10. The display device according to claim 9, wherein a thickness of the support member is same as a thickness of the second adhesive layer.

11. The display device according to claim 9, wherein a thickness of the support member is smaller than a thickness of the second adhesive layer.

12. The display device according to claim 11, wherein a difference between a thickness of the support member and a thickness of the second adhesive layer is 0.02 μm or less than 0.02 μm.

13. The display device according to claim 1, wherein the opening includes an upper area and a lower area having different widths, and
wherein a width of the upper area of the opening is larger than a width of the lower area of the opening.

14. The display device according to claim 13, wherein the second support substrate includes a protrusion protruding toward the lower area of the opening.

15. The display device according to claim 14, wherein a protruding length of the protrusion is 0.5 μm or less than 0.5 μm, and
wherein the protrusion overlaps at least a portion of the support member.

16. The display device according to claim 1, wherein a distance from a bottom surface of the support member to a top surface of the first support substrate is 0.01 mm to 0.03 mm.

17. A display device, comprising:
a display panel including a folding area and non-folding areas positioned on both sides of the folding area, the non-folding areas including a base substrate and a display part disposed on the base substrate;
a support member disposed below the display panel and disposed to correspond to the folding area;
a first adhesive layer disposed below the display panel and disposed to surround the support member;
a first support substrate disposed below the first adhesive layer, the first support substrate including a first opening corresponding to the support member;
a second adhesive layer disposed below the first support substrate, the second adhesive layer including a second opening corresponding to the support member; and
a second support substrate disposed below the second adhesive layer, the second support substrate including a plurality of opening patterns corresponding to the folding area.

18. The display device according to claim 17, wherein the support member is glass,
wherein a width of the support member decreases toward a bottom of the support member, and
wherein the support member and the first adhesive layer are in direct contact with a bottom surface of the base substrate.

19. The display device according to claim 17, wherein the support member is a polymer film and further includes a third adhesive layer disposed between the base substrate and the polymer film, and
wherein the support member and the first adhesive layer are in direct contact with a lower surface of the third adhesive layer.

20. The display device according to claim 17, wherein the first opening includes an upper area and a lower area having different widths, and
wherein a width of the upper area is larger than a width of the lower area.
